(19) United States
(12) Patent Application Publication
(10) Pub. No.: US 2008/0029892 A1
(43) Pub. Date: Feb. 7, 2008

(54) METHOD OF FABRICATING SEMICONDUCTOR DEVICE

(76) Inventor: Soon-Wook Jung, Jecheonam-do (KR)

Correspondence Address: SHERR & NOURSE, PLLC, 620 HERNDON PARKWAY, SUITE 200, HERNDON, VA, 20170, US

(21) Appl. No.: 11/832,310

(22) Filed: Aug. 1, 2007

(30) Foreign Application Priority Data
Aug. 7, 2006 (KR) 10-2006-0074326

(51) Int. Cl. H01L 21/44; H01L 23/48

(52) U.S. Cl. 257/751; 438/653; 257/E23.01; 257/E21.577

(57) ABSTRACT

A method of fabricating a semiconductor device including at least one of the following steps: Forming a metal layer on and/over a semiconductor substrate. Forming a diffusion barrier film on and/over the metal layer. Forming a metal layer pattern and an diffusion barrier film pattern by etching the metal layer and the diffusion barrier film. Forming an insulating film covering the metal layer pattern and the diffusion barrier film pattern. Forming a via hole using a photoresist pattern on and/or over the insulating film. Forming a contact by filling the via hole with an electrically conductive material.

This application claims the benefit under 35 U.S.C. 119 to Korean Patent Application No. 10-2006-0074326, filed on Aug. 7, 2006, which is hereby incorporated by reference in its entirety.

### BACKGROUND

When manufacturing some semiconductor devices with relatively small scale design rules, it may be relatively difficult to etch a via hole. For example, when a via is formed on and/or over a Titanium Nitride (TiN) film disposed on a lower aluminum metal layer, excessive polymer may be built up and stop the formation of the via at the TiN film. When excessive polymer is formed, polymer fumes may inadvertently fill a via hole and not be discharged. Excessive polymer buildup may increase the contact resistance of a via hole, which may cause defects in a semiconductor device.

Polymer buildup problems may be relatively severe in a process of manufacturing a semiconductor device that uses a Standard Mechanical Interface (SMIF) pod. For example, polymer buildup problems may occur in a wafer positioned at a slot below an uppermost slot of a cassette of a SMIF pod. Standard Mechanical Interface (SMIF) may be used to preventing human error in a semiconductor manufacturing process. An SMIF apparatus is a peripheral device in a semiconductor device manufacturing system that may perform a semiconductor manufacturing process. A SMIF apparatus may be used to load/unload a wafer or a wafer cassette containing wafers into/from the semiconductor device manufacturing system.

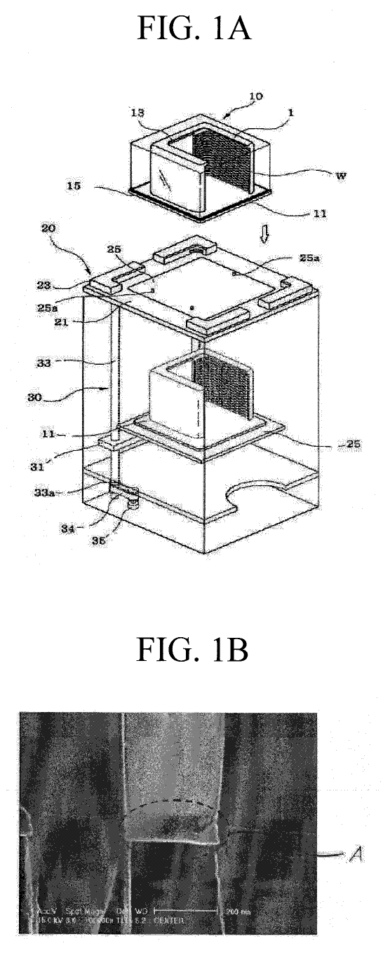

Example FIG. 1A illustrates a SMIF apparatus. A SMIF apparatus may include SMIF pod 10 which may receive wafer cassette 1. SMIF port 20 may be used for loading and unloading SMIF pod 10. Driving unit 30 disposed in SMIF port 20 may move wafer cassette 1 in a vertical direction.

SMIF pod may include bedplate 11 and SMIF stage 25. SMIF stage fixing part 25a may serve to fix a SMIF pod when the SMIF pod is loaded on a SMIF apparatus. Part 31 may move a SMIF stage up and down by the driving force provided from Z shaft 33. Z shaft 33 may serve as a driving shaft that transmits a driving force for vertical movement in the SMIF apparatus. Pulley 33a may be for fixing a driving belt. Belt 34 may be for transmitting a driving force from driving motor 35. Driving motor 35 may be for vertical movement in a SMIF apparatus.

SMIF pod 10 may includes a pod door 11 at the bottom of SMIF pod 10. A pod cover 13 may cover wafer cassette 1 which is over pod door 11, Wafer cassette may contain wafers W arranged therein. It may be preferable to prevent outside air from entering into SMIF pod 10. Accordingly, sealing member 15 (e.g. made of rubber) may be disposed over pod cover 13 (e.g. at a portion where the pod cover 13 is in contact with the pod door 11) to prevent air from entering into SMIF pod 10. SMIF port 20 may include a port plate 21 that horizontally maintains the bottom surface of SMIF pod 10. SMIF port 20 may include an L-shaped guide rail 23 for guiding the SMIF pod 10 and a port door 25 for carrying the wafer cassette 1 on the pod door 11.

In a SMIF pod of a SMIF apparatus, residue (e.g. gas fumes) may formed on the surface of a wafer after a process is completed. For example, residue may form after an etching process or a deposition process using a C—H-based gas is performed when there is a delay before the next process. C—H-based fumes may react with the surface of a wafer to form polymer particles (e.g. polymer fumes). Accordingly, as indicated by a dotted line A in example FIG. 1B, polymer fumes may fill a via hole, which may increase contact resistance of a via hole and/or reduce semiconductor device yield.

### SUMMARY

Embodiments relate to a method of fabricating a semiconductor device. In embodiments, a via hole may be formed without inadvertently increasing contact resistance of a via hole from polymer buildup. Embodiment may maximize manufacturing yield by minimizing contact resistance related failure in via holes.

Embodiments relate to a method of fabricating a semiconductor device including at least one of the following steps: Forming a metal layer on and/over a semiconductor substrate. Forming a diffusion barrier film on and/over the metal layer. Forming a metal layer pattern and an diffusion barrier film pattern by etching the metal layer and the diffusion barrier film. Forming an insulating film covering the metal layer pattern and the diffusion barrier film pattern. Forming a via hole using a photoresist pattern on and/or over the insulating film. Forming a contact by filling the via hole with an electrically conductive material.

In embodiments, a metal layer may include at least one of copper and aluminum. In embodiments, a diffusion barrier film may include TiN. In embodiments, forming a via hole may include at least one of the following steps: Performing a main etching process to etch an insulating film through a photoresist pattern. Performing an over etching process to etch the diffusion barrier film to a specified depth. Performing a post etch treatment (PET) process to remove polymer reaction products generated through the main etching process and the over etching process.

In embodiments, a PET process may be performed using a Magnetically Enhanced Reactive Ion Etch (MERIE) dry etching apparatus under at least one of the following process conditions: Cathode temperature between approximately 15° C. and approximately 28° C. Sidewall temperature between approximately 55° C. and 65° C. Upper electrode temperature between approximately 55° C. and 65° C. RF power between approximately 250 W and approximately 350 W. Ar gas flow rate between approximately 200 sccm and approximately 320 sccm. O2 gas flow rate between approximately 10 sccm and approximately 22 sccm. SF6 flow rate between approximately 10 sccm and approximately 20 sccm.

In embodiments, a PET process is performed at a process atmosphere pressure between approximately 20 mTorr and approximately 35 mTorr. In embodiments, polymer reaction products react with O2 gas to be discharged as CO2 gas.

### DRAWINGS

Example FIG. 1A illustrates a SMIF apparatus.

Example FIG. 1B illustrates polymer fumes filling a via hole.

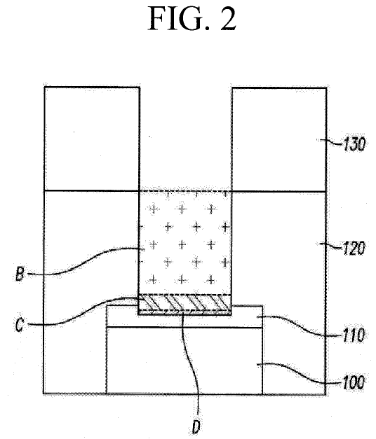

Example FIG. 2 illustrates a process of forming a via hole, according to embodiments.

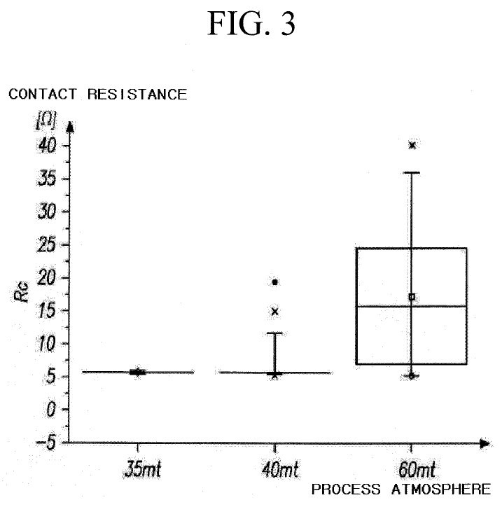

Example FIG. 3 is a graph illustrating measured contact resistances in a via hole formed by varying a process atmosphere pressure, according to embodiments.

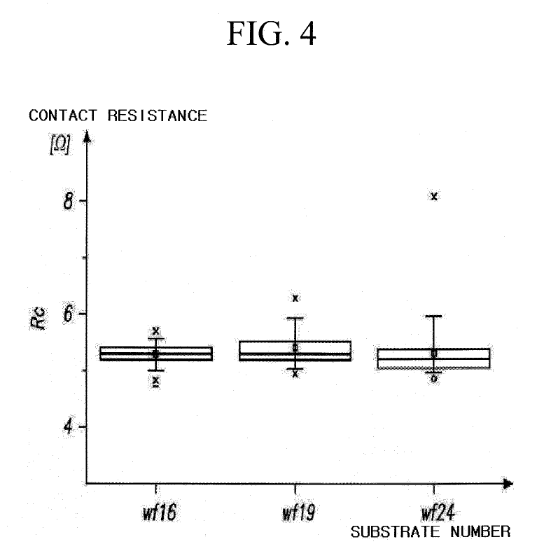

Example FIG. 4 is a graph illustrating measured via contact resistance in a plurality of semiconductor substrates having a via hole, according to embodiments.

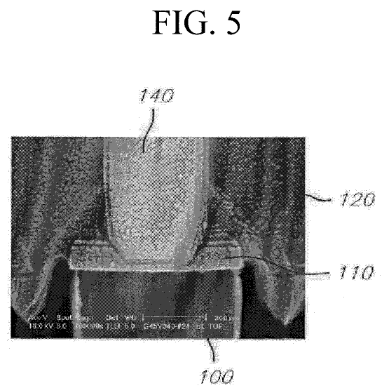

Example FIG. 5 is a scanning electron microscope (SEM) image illustrating a via hole formed according to embodiments.

### DESCRIPTION

Example FIG. 2 illustrates a cross-sectional view illustrating a process of forming a via hole, according to embodiments. In embodiments, TiN pattern 110 (which may serve as a diffusion barrier film) may be formed on and/or over metal pattern 100. In embodiments, metal pattern 100 comprises aluminum. Metal pattern 100 may be formed on and/or over a semiconductor substrate.

In embodiments, a TiN film may be deposited on an aluminum layer to have a thickness of about 50 Å. TiN film may be deposited by thermal decomposition using a Tetrakis-dimethyl-amino-titanium (TDMAT) material, in accordance with embodiments. In embodiments, a plasma process may be performed on the deposited thermal TiN film using H2 plasma gas and N2 plasma gas in a chemical vapor deposition (CVD) chamber, thereby forming a CVD TiN film. When a plasma process is performed on a thermal TiN film, the thickness of the thermal TiN film may be reduced. Accordingly, the CVD TiN film may be formed to have a thickness of about 25 Å.

In embodiments, a TiN film deposition process may be performed multiple times. For example, a CVD TiN film may be formed to have a thickness of about 50 Å. Dry etching (e.g. Reactive ion etching (RIE)) may be performed to form TiN pattern 110 on and/or over metal pattern 100 (e.g. made of aluminum). However, a CVD TiN film having a desired thickness (e.g. 50 Å) may be formed through one process, in accordance with embodiments. In embodiments, CVD TiN film 110 may be formed to have a thickness between approximately 30 Å and approximately 100 Å, by controlling the thickness of the thermal TiN film.

Insulating layer 120 (e.g. including SiO2) may be formed on and/or over the metal pattern 100 (e.g. made of aluminum) and TiN pattern 110, in accordance with embodiments. In embodiments, photoresist pattern 130 may serve as a via pattern for forming a via in insulating layer 120.

When a via is formed using photoresist pattern 130, a first etching may be performed to etch a portion B of insulating layer 120, in accordance with embodiments. In embodiments, portion B may not extend all the way through insulating layer 120, leaving a portion of insulating layer 120 unetched over TiN pattern 110. In embodiments, an unetched portion of insulating layer 120 over TiN pattern 110 may be a predetermined thickness (e.g. a thickness of approximately 200 Å to 500 Å). In embodiments, a first etching may entirely remove insulating layer 120 over TiN pattern 110.

After a first etching is performed, over etching may be performed to etch the TiN pattern 110, in accordance with embodiments. In embodiments, over etching may include etching portions C and D of insulating layer 120 and/or TiN pattern 110. Over etching may be performed to a predetermined depth (e.g. a depth of 10 Å), in accordance with embodiments. In embodiments, over etching may be performed at a relatively low etching rate (e.g. an etching ratio of the TiN pattern 110 to the SiO2 insulating layer 120 is 5 to 1˜100 to 1). In accordance with embodiments, by over etching at a relatively low etching rate, it may be possible to reduce generation of polymer particles (e.g. polymer fumes and/or polymer reaction products).

In embodiments, a plurality of etching processes (e.g. first etching and over etching) may be performed, which may result in polymer particles (e.g. polymer reaction products and/or polymer fumes) remaining at the bottom of via hole, which are represented by portion D in example FIG. 2, which may cause a contact resistance complications in the via hole. In embodiments, a post etch treatment (PET) process may be performed to remove polymer particles after an over etching process. A PET process may remove polymer particles (e.g. polymer reaction products and/or polymer fumes) remaining in portion D, in accordance with embodiments.

Polymer particles (e.g. polymer reaction products and/or polymer fumes) remaining at the bottom of a via hole may be broken into fine particles while the bond is broken by fluorine (F) and argon (Ar) in a PET process, in accordance with embodiments. In embodiments, polymer particles (e.g. polymer reaction products) that include Carbon (C) may be broken into fine particles. Since many components of polymer particles remaining in a bottom portion of the via hole have carbon (C), a PET process may be performed using O2 gas to accelerate formation of CO2 from polymer particles, in accordance with embodiments. In embodiments, the reaction products converted into CO2 may be pumped out of a chamber. In embodiments, both reaction products converted into CO2 and reaction products that are not converted into CO2 may be pumped out of the chamber.

In embodiments, removal of polymer particles may not be entirely performed by only using O2 gas. Accordingly, in embodiments, a PET process is performed as an in-situ process in the same chamber as via etching, without having to transfer a wafer into another apparatus or chamber. A PET process may be a different process than a photoresist strip, which may be performed after the via hole etching or an after-treatment process in another processing apparatus.

In embodiments, a PET process for via hole etching may be performed using a Magnetically Enhanced Reactive Ion Etch (MERIE) dry etching apparatus under at least one of the following the process conditions: Cathode temperature between approximately 15° C. and 28° C. Sidewall temperature between approximately 55° C. and 65° C. Upper electrode temperature between approximately 55° C. and 66° C. RF power between approximately of 250 W and 350 W. Ar gas flow rate between approximately 200 sccm and 320 sccm. O2 gas flow rate between approximately 10 sccm and 22 sccm. SF6 flow rate between approximately 10 sccm and 20 sccm.

In accordance with embodiments, a PET process may be performed at a process atmosphere pressure between approximately 20 mTorr and 35 mTorr, which may result in polymer particles (e.g. polymer reaction products and polymer fumes) being pumped out at a maximum level. Accordingly, the polymer reaction products such as polymer fumes may be removed from a via hole.

As illustrated in example FIG. 3, it is illustrated that via contact resistance has a relatively uniform distribution, in accordance with embodiments. In embodiments, an ionization rate of a processing gas may be maximized when process atmosphere pressure is relatively and the process reaction is more active at higher pressures. As illustrated in example FIG. 4, when a PET process is performed at an O2 gas flow rate of approximately 10 sccm to approximately 22 sccm, all semiconductor substrates (e.g. semiconductor substrate wf16, semiconductor substrate wf19, and semiconductor substrate wf24) have uniform via contact resistances less than approximately 7Ω, in accordance with embodiments.

As illustrated in scanning electron microscope (SEM) image in example FIG. 5, after a via hole is formed through the PET process, contact 140 is formed in the via hole (e.g. using tungsten), in accordance with embodiments. In embodiments, since polymer particles (e.g. polymer reaction products and/or polymer fumes) have been substantially removed from a via hole, contact 140 may be formed with negligible levels of impurities. Accordingly, negligible levels of impurities may prevent relatively high contact resistances that may cause contact failure, in accordance with embodiments. In embodiments, negligible levels of impurities may maximize semiconductor device manufacturing by minimizing contact resistance failure.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a second metal layer over a semiconductor substrate;
forming an insulating layer over the second metal layer;
performing a first etching process through the insulating layer over the second metal layer to form a first portion of a via;
performing an over etching process through at least one of the insulating layer and the second metal layer to form a second portion of the via; and
performing a post etch treatment in the via.

2. The method of claim 1, wherein the etch rate of the over etching process is less than the etch rate of the first etching process.

3. The method of claim 1, wherein the post etch treatment removes polymer particles from the via.

4. The method of claim 3, wherein the post etch treatment removes polymer particles from the via by polymer particles reacting with O2 gas to be discharged as CO2 gas.

5. The method of claim 3, wherein the polymer particles include at least one of polymer reaction products and polymer fumes generated through the first etching process and the over etching process.

6. The method of claim 1, wherein the second metal layer is a diffusion barrier film.

7. The method of claim 1, wherein the second metal layer comprises Titanium Nitride.

8. The method of claim 1, comprising forming a first metal layer, wherein:
the first metal layer is formed prior to forming the second metal layer; and
the second metal layer is formed over the first metal layer.

9. The method of claim 8, wherein the first metal layer comprises Aluminum.

10. The method of claim 1, wherein the post etch treatment is performed using a Magnetically Enhanced Reactive Ion Etch dry etching apparatus under at least one of:
cathode temperature between approximately 15° C. and 28° C.;
sidewall temperature between approximately 55° C. and 65° C.;
upper electrode temperature between approximately 55° C. and 66° C.;
RF power between approximately of 250 W and 350 W;
Ar gas flow rate between approximately 200 sccm and 320 sccm;
O2 gas flow rate between approximately 10 sccm and 22 sccm; and
SF6 flow rate between approximately 10 sccm and 20 sccm.

11. The method of claim 1, wherein the post etch treatment is performed at a process atmosphere pressure between approximately 20 mTorr and approximately 35 mTorr.

12. An apparatus comprising:
a second metal layer formed over a semiconductor substrate;
an insulating layer formed over the second metal layer;
a via formed through a first etching process through the insulating layer over the second metal layer to form a first portion of the via, an over etching process through at least one of the insulating layer and the second metal layer to form a second portion of the via, and a post etch treatment in the via.

13. The apparatus of claim 12, wherein the etch rate of the over etching process is less than the etch rate of the first etching process.

14. The apparatus of claim 12, wherein the post etch treatment removes polymer particles from the via by polymer particles reacting with O2 gas to be discharged as CO2 gas.

15. The apparatus of claim 12, wherein the second metal layer is a diffusion barrier film.

16. The apparatus of claim 12, wherein the second metal layer comprises Titanium Nitride.

17. The apparatus of claim 12, comprising forming a first metal layer, wherein:
the first metal layer is formed prior to forming the second metal layer; and
the second metal layer is formed over the first metal layer.

18. The apparatus of claim 17, wherein the first metal layer comprises Aluminum.

19. The apparatus of claim 12, wherein the post etch treatment is performed using a Magnetically Enhanced Reactive Ion Etch dry etching apparatus under at least one of:
cathode temperature between approximately 15° C. and 28° C.;
sidewall temperature between approximately 55° C. and 65° C.;
upper electrode temperature between approximately 55° C. and 66° C.;
RF power between approximately of 250 W and 350 W;
Ar gas flow rate between approximately 200 sccm and 320 sccm;
O2 gas flow rate between approximately 10 sccm and 22 sccm; and
SF6 flow rate between approximately 10 sccm and 20 sccm.

20. The apparatus of claim 12, wherein the post etch treatment is performed at a process atmosphere pressure between approximately 20 mTorr and approximately 35 mTorr.
